(19) United States
(12) Patent Application Publication
(10) Pub. No.: US 2009/0256830 A1
(43) Pub. Date: Oct. 15, 2009

(54) HYBRID DISPLAY

(75) Inventors: Gunnar KLINGHULT, Lund (SE); Mats KLEVERMAN, Helsingborg (SE); Magnus JENDBRO, Staffanstorp (SE)

Correspondence Address: HARRITY & HARRITY, LLP, 11350 RANDOM HILLS ROAD, SUITE 600, FAIRFAX, VA, 22030, US

(73) Assignee: SONY ERICSSON MOBILE COMMUNICATIONS AB, Lund (SE)

(21) Appl. No.: 12/102,327

(22) Filed: Apr. 14, 2008

(51) Int. Cl. G09G 5/00

(52) U.S. Cl. 345/211; 345/3.1

(57) ABSTRACT

A mobile communication device comprising a display assembly comprising a plurality of transistors, where each of the plurality of transistors includes a light-emitting region and a non-light-emitting region and a plurality of organic light emitting diodes (OLEDs), where the plurality of OLEDs are located directly on top of the non-light-emitting regions of the plurality of transistors; and logic configured to select and activate at least one of the plurality of transistors or the plurality of OLEDs to display information.

### BACKGROUND

Devices, such as handheld mobile communication devices, typically include display devices that provide visual information to a user. Handheld mobile communication devices also typically operate from batteries, where the display devices commonly require/consume the greatest amount of power from the batteries. Low power displays do not provide adequate resolution for performing functions on the mobile communication devices while high resolution displays consume battery power too quickly.

### SUMMARY

According to one aspect, a mobile communication device is provided. The mobile communication device may comprise a display assembly including a number of transistors, where each of the number of transistors includes a light-emitting region and a non-light-emitting region; and a number of organic light emitting diodes (OLEDs), where the number of OLEDs are located directly on top of the non-light-emitting regions of the number of transistors; a transistor driving circuit to provide current to the number of transistors; an OLED driving circuits to provide current to the number of OLEDs; and logic configured to: receive and determine a type of information for display, and select at least one of the transistor driving circuit or the OLED driving circuit based on the determined type of received information to display the received information.

Additionally, the logic may be further configured to: select the OLED driving circuit when the received information for display is determined to be a first type of information; and select the transistor driving circuit when the received information for display is determined to be a second type of information.

Additionally, the first type of information may include at least one of a time of day or an icon.

Additionally, the mobile communication device may further comprise a keypad for entering characters.

Additionally, the second type of information may include at least one of text messages or characters entered via the keypad.

According to another aspect, a method may be provided. The method may comprise providing a display, where the display may include a first display assembly located on top of components of a second display assembly; receiving information for display; determining that the received information is one of a first type of information or a second type of information; and selecting and activating one of the first display assembly or the second display assembly based on a determined information type to display the received information.

Additionally, the first display assembly may include organic light emitting diodes (OLEDs).

Additionally, the second display assembly may include transistors.

Additionally, the OLEDs may be located on top of a non-light-emitting portion of the transistors.

Additionally, the selecting and activating one of the first or second display assemblies based on the determined information type to display the received information further includes: selecting the first display assembly when the received information is determined to be the first type of information; and selecting the second display assembly when the received information is determined to be the second type of information.

Additionally, the first type of information may include an icon.

Additionally, the second type of information may include information other than an icon.

Additionally, the first display assembly may include a pattern of OLEDs arranged to form the icon.

Additionally, the icon may include at least one of a message icon, a signal strength icon or a battery power icon.

Additionally, the first type of information may include a time of day.

Additionally, the first display assembly does not require backlighting.

According to yet another aspect, a device may be provided. The device may comprise a display assembly comprising: a number of transistors, where each of the number of transistors includes a light-emitting region and a non-light-emitting region; and a number of organic light emitting diodes (OLEDs), wherein the number of OLEDs are located directly on top of the non-light-emitting regions of the number of transistors; and logic configured to: activate at least one of the number of transistors or the number of OLEDs to display information.

Additionally, the logic may be further configured to select and activate the number of OLEDs when the information is an icon or time of day information; and select and activate the number of TFTs when the information is video information or character information.

Additionally, the number of OLEDs are arranged in a number of groups, where each group forms a pattern that is associated with an icon.

Additionally, the logic may be further configured to select and activate the plurality of OLEDs and the plurality of transistors when bright ambient light conditions are determined.

### BRIEF DESCRIPTION OF THE DRAWINGS

The accompanying drawings, which are incorporated in and constitute a part of this specification, illustrate one or more embodiments described herein and, together with the description, explain these embodiments. In the drawings:

FIG. 1 is a diagram of an exemplary implementation of a mobile terminal;

FIG. 2 illustrates a functional diagram of the mobile terminal of FIG. 1:

FIG. 3 illustrates a functional diagram of the display logic of FIG. 2;

FIGS. 4A-4F illustrate exemplary displays;

FIG. 5 is a flowchart of exemplary processing;

FIG. 6 shows an example of displaying information; and

FIG. 7 shows another example of displaying information.

### DETAILED DESCRIPTION

The following detailed description refers to the accompanying drawings. The same reference numbers in different drawings may identify the same or similar elements. Also, the following detailed description does not limit the embodiments.

Exemplary implementations of the embodiments will be described in the context of a mobile communications terminal. It should be understood that a mobile communication terminal is an example of a device that can employ a display, as described herein, and should not be construed as limiting the types or sizes of devices or applications that can use implementations of displays described herein. For example, displays, as described herein, may be used on desktop communication devices, household appliances, such as microwave ovens and/or appliance remote controls, automobile radio faceplates, industrial devices, such as testing equipment, etc.

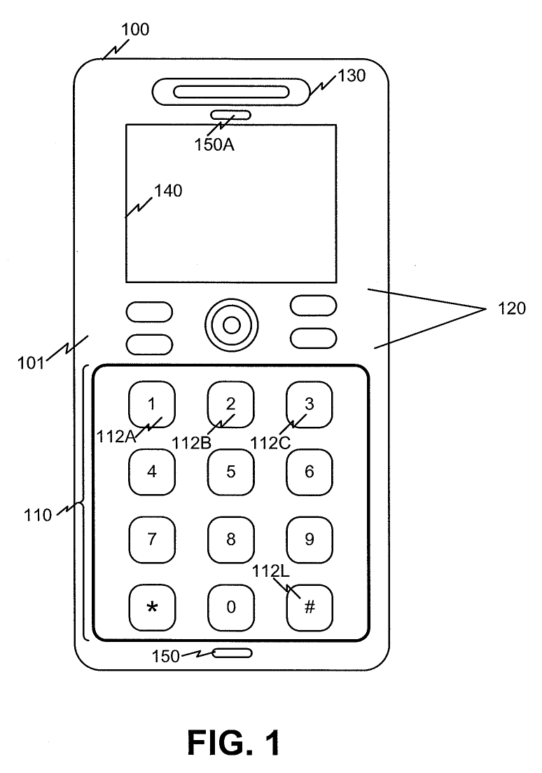

FIG. 1 is a diagram of an exemplary implementation of a mobile terminal, as described herein. Mobile terminal 100 (hereinafter terminal 100) may be a mobile communication device. As used herein, a “mobile communication device” and/or “mobile terminal” may include a radiotelephone; a personal communications system (PCS) terminal that may combine a cellular radiotelephone with data processing, facsimile, and data communications capabilities; a personal digital assistant (PDA) that can include a radiotelephone, pager, Internet/intranet access, web browser, organizer, calendar, and/or global positioning system (GPS) receiver; a laptop and/or palmtop receiver or other appliance that includes a radiotelephone transceiver; or any other type of mobile device that includes a display.

Terminal 100 may include housing 101, keypad area 110 containing keys 112A-L, control keys 120, speaker 130, display 140, and microphones 150 and 150A. Housing 101 may include a structure configured to hold devices and components used in terminal 100. For example, housing 101 may be formed from plastic, metal, or composite and may be configured to support keypad area 110, control keys 120, speaker 130, display 140 and microphones 150 and/or 150A.

Keypad area 110 may include devices and/or logic that can be used to display images to a user of terminal 100 and to receive user inputs in association with the displayed images. For example, a number of keys 112A-L (collectively keys 112) may be displayed via keypad area 110. Implementations of keypad area 110 may be configured to receive a user input when the user interacts with keys 112. For example, the user may provide an input to keypad area 110 directly, such as via the user's finger, or via other devices, such as a stylus. User inputs received via keypad area 110 may be processed by components or devices operating in terminal 100. In one example, keypad area 110 may be covered by a single plate of glass with characters associated with keys 112 back-printed on the glass cover. In another example, keys 112 may be formed of buttons with characters associated with each key being printed on each of keys 112. For example, each key 112 may have key information associated therewith, such as numbers, letters, symbols, etc. In another example, keypad area 110 may be configured as an LCD display, where information associated with each of keys 112 may be displayed via the LCD display.

Control keys 120 may include buttons that permit a user to interact with terminal 100 to cause terminal 100 to perform an action, such as to display a text message via display 140, raise or lower a volume setting for speaker 130, etc.

Speaker 130 may include a device that provides audible information to a user of terminal 100. Speaker 130 may be located in an upper portion of terminal 100 and may function as an ear piece when a user is engaged in a communication session using terminal 100. Speaker 130 may also function as an output device for music and/or audio information associated with games and/or video images played on terminal 100.

Display 140 may include a device that provides visual information to a user. For example, display 140 may provide information regarding information entered via keys 112, incoming or outgoing calls, text messages, games, phone books, the current date/time, volume settings, etc., to a user of terminal 100. Implementations of display 140 may be implemented as black and white or color displays, such as liquid crystal displays (LCDs).

Microphones 150 and/or 150A may, each, include a device that converts speech or other acoustic signals into electrical signals for use by terminal 100. Microphone 150 may be located proximate to a lower side of terminal 100 and may be configured to convert spoken words or phrases into electrical signals for use by terminal 100. Microphone 150A may be located proximate to speaker 130 and may be configured to receive acoustic signals proximate to a user's ear while the user is engaged in a communications session using terminal 100.

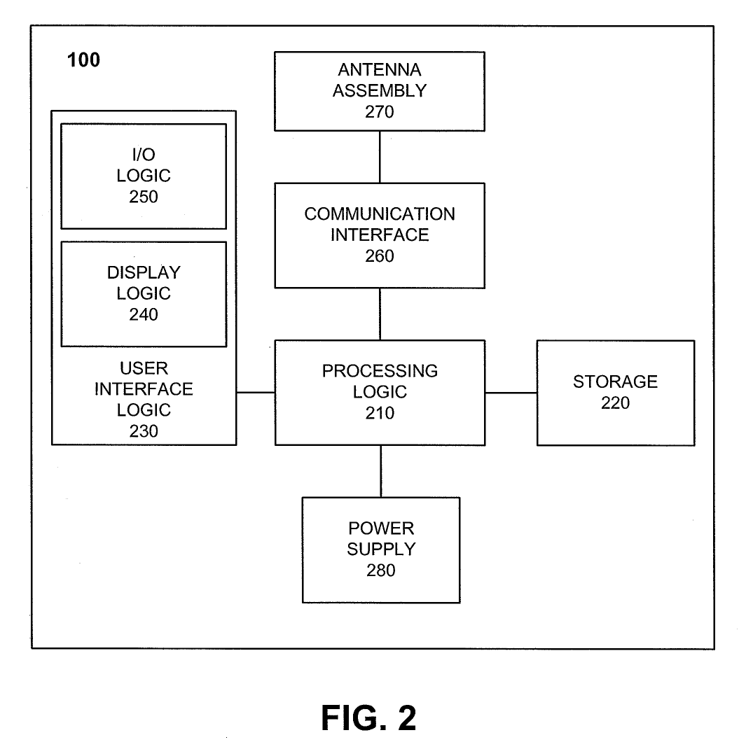

FIG. 2 illustrates a functional diagram of mobile terminal 100 consistent with the principles described herein. As shown in FIG. 2, terminal 100 may include processing logic 210, storage 220, user interface logic 230, display logic 240, input/output (I/O) logic 250, communication interface 260, antenna assembly 270, and power supply 280.

Processing logic 210 may include a processor, a microprocessor, an application specific integrated circuit (ASIC), a field programmable gate array (FPGA), or the like. Processing logic 210 may include data structures or software programs to control operation of terminal 100 and its components. Implementations of terminal 100 may use an individual processing logic component or multiple processing logic components, such as processing logic components operating in parallel. Storage 220 may include a random access memory (RAM), a read only memory (ROM), a magnetic or optical disk and its corresponding drive, and/or another type of memory to store data and instructions that may be used by processing logic 210.

User interface logic 230 may include mechanisms, such as hardware and/or software, for inputting information to terminal 100 and/or for outputting information from terminal 100. In one implementation, user interface logic 230 may include display logic 240 and input/output logic 250.

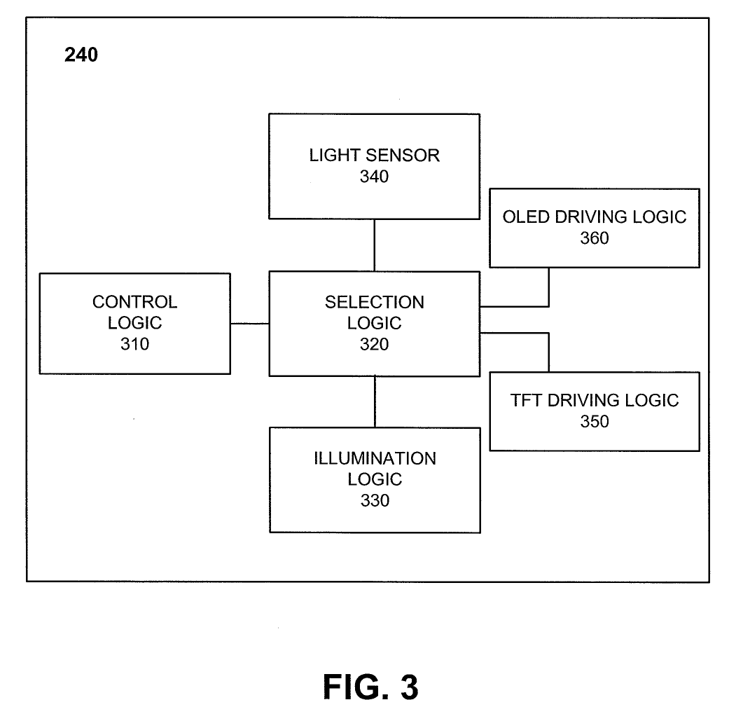

Display logic 240 may include mechanisms, such as hardware and/or software, used to control display 140. As will be described in greater detail below in FIG. 3, display logic 240 may include hardware and/or software for selecting and driving different types of display assemblies within display 140 based on the determined type of information/input to be displayed. For example, display logic 240 may receive information to be displayed and select the appropriate type of display assembly within display 140.

Input/output logic 250 may include hardware and/or software to accept user inputs and to make information available to a user of terminal 100. Examples of input and/or output mechanisms associated with input/output logic 250 may include a speaker (e.g., speaker 130) to receive electrical signals and output audio signals, a microphone (e.g., microphone 150 or 150A) to receive audio signals and output electrical signals, buttons (e.g., control keys 120) to permit data and control commands to be input into terminal 100, and/or a display (e.g., display 140) to output visual information.

Communication interface 260 may include, for example, a transmitter that may convert base band signals from processing logic 210 to radio frequency (RF) signals and/or a receiver that may convert RF signals to base band signals. Alternatively, communication interface 260 may include a transceiver to perform functions of both a transmitter and a receiver. Communication interface 260 may connect to antenna assembly 270 for transmission and reception of the RF signals. Antenna assembly 270 may include one or more antennas to transmit and receive RF signals over the air. Antenna assembly 270 may receive RF signals from communication interface 260 and transmit them over the air and receive RF signals over the air and provide them to communication interface 260.

Power supply 280 may include one or more power supplies that provide power to components of terminal 100. For example, power supply 280 may include one or more batteries and/or connections to receive power from other devices, such as an accessory outlet in an automobile, an external battery, or a wall outlet. Power supply 280 may also include metering logic to provide the user and components of terminal 100 with information about battery charge levels, output levels, power faults, etc.

As will be described in detail below, terminal 100, as described herein, may perform certain operations relating to selecting and driving different display assemblies based on a determined type of information to be displayed. Terminal 100 may perform these operations in response to processing logic 210 and/or display logic 240 executing software instructions contained in a computer-readable medium, such as storage 220. A computer-readable medium may be defined as a physical or logical memory device and/or carrier wave.

The software instructions may be read into storage 220 from another computer-readable medium or from another device via communication interface 260. The software instructions contained in storage 220 may cause processing logic 210 to perform processes that will be described later. Alternatively, hardwired circuitry may be used in place of or in combination with software instructions to implement processes consistent with the principles described herein. Thus, implementations described herein are not limited to any specific combination of hardware circuitry and software.

FIG. 3 illustrates a functional diagram of the display logic 240 of FIG. 2 consistent with the principles of the embodiments. Display logic 240 may include control logic 310, selection logic 320, illumination logic 330, light sensor 340, thin film transistor (TFT) driving logic 350 and organic light emitting diode (OLED) driving logic 360.

Control logic 310 may include logic that controls the operation of display logic 240. Control logic 310 may receive signals from processing logic 210, user interface logic 230 and I/O logic 250 that includes information to be displayed via display 140. Control logic 310 may transmit signals and information to selection logic 320. Control logic 310 may be implemented as standalone logic or as part of processing logic 210. Moreover, control logic 310 may be implemented in hardware and/or software.

Selection logic 320 may include devices and logic to receive information to be displayed and to determine how to control components within display logic 240 (to display the received information) based on the determined type of received information. For example, selection logic 320 may identify and/or classify received information into a first and second type, for example. Information such as the time of day (clock function), a message icon, battery power icon and a signal strength icon, may be identified by selection logic 320 as a first type of information to be displayed. Other types of information to be displayed, such as video clips, images, text messages, web-pages, a menu of choices, characters/numbers input via keys 112, may be identified by selection logic 320 as a second type of information. Based on the determined type of information, selection logic 320 may select the appropriate driving logic to display the received information. For example, selection logic 320 may select OLED driving logic 360 to display the first type of received information using an OLED display assembly and selection logic 320 may select TFT driving logic 350 to display the second type of received information using a TFT display assembly. Selection logic 320 may also receive signals from light sensor 340 and may transmit signals to illumination logic 330 and the appropriate driving logic based on the received signals from light sensor 340. Additionally, selection logic 320 may select a driving logic based on a determined state of terminal 100/display 140. For example, selection logic 320 may select OLED driving logic 360 to display received information if mobile terminal 100 is in a “sleep” or “power save” mode and selection logic 320 may select TFT driving logic 350 to display received information using a TFT display when display 140 of terminal 100 is in an active state (i.e. already displaying information using the TFT display assembly).

Illumination logic 330 may include logic to provide backlighting to a lower surface of display 140. Illumination logic 330 may receive signals from selection logic 320 to provide backlighting to be used with LCD-based implementations of display 140 to make images brighter and to enhance the contrast of displayed images. Implementations of illumination logic 330 may employ light emitting diodes (LEDs) or other types of devices to illuminate portions of a display device. Illumination logic 330 may provide light within a narrow spectrum, such as a particular color, or via a broader spectrum, such as full spectrum lighting.

Light sensor 340 may include a photo-electric sensor that senses and determines an amount of ambient light. Light sensor 340 may output a signal to selection logic 320, where the strength of the signal indicates the amount of ambient light sensed by light sensor 340. In other embodiments, light sensor 340 may include a light scanner.

TFT driving logic 350 may include logic and devices that provide selecting and driving/activating signals to a TFT display assembly within display 140. For example, TFT driving logic 350 may select and drive appropriate thin film transistors to display received information. Implementations of TFT driving logic 350 may be configured as transistors or other types of switches to switch on/off power supplied (from power supply 280) to the thin film transistors. In other examples, one switch included in TFT driving logic 350 may switch/control power supplied to a number or group of thin film transistors.

OLED driving logic 360 may include logic and devices that provide selecting and driving/activating signals to an OLED display assembly. For example, OLED driving logic 360 may select and drive appropriate organic light emitting diodes to display received information. Implementations of OLED driving logic 360 may include transistors used to switch on/off power supplied (from power supply 280) to the organic light emitting diodes. In one example, one switch included in OLED driving logic 360 may control power to a group or number of OLEDs.

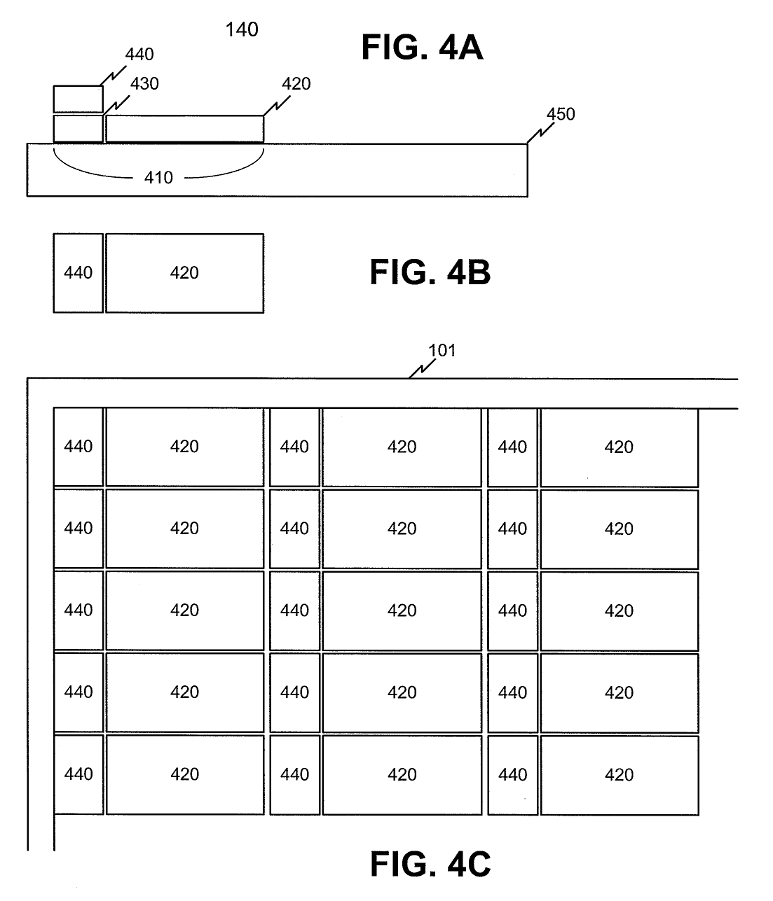

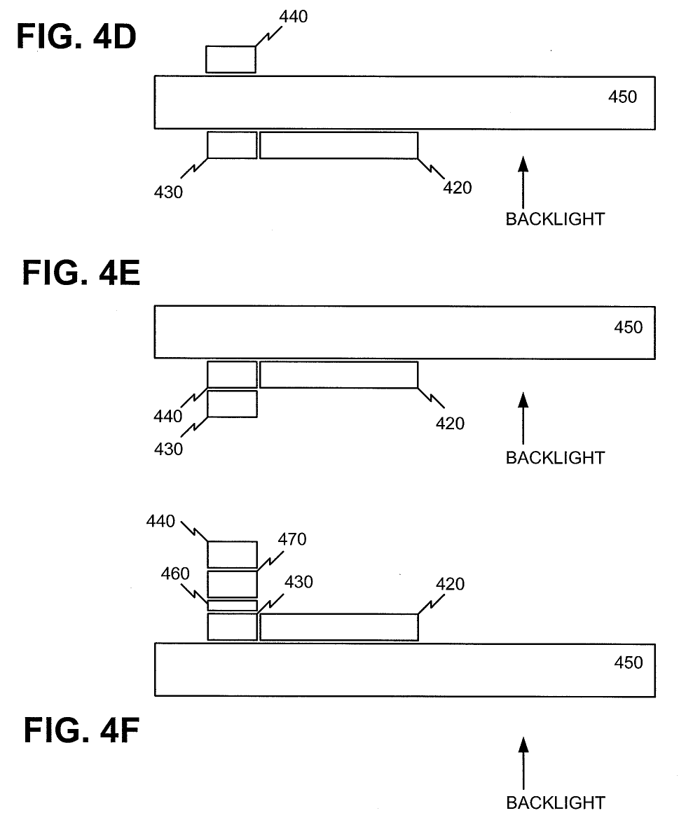

Further details of a thin film transistor display assembly and an organic light emitting diode display assembly included within display 140 are shown in FIGS. 4A to 4F.

FIGS. 4A to 4F illustrate exemplary embodiments of display 140. FIG. 4A shows a side view of an organic light emitting diode 440 located on top of a thin film transistor 410 that may be included within display 140.

Thin film transistor (TFT) 410 may include silicon layers which form a transistor which includes a pixel portion 420 and a driving portion 430. In other embodiments, element 410 (which includes a driving and pixel portions 420 and 430) may be a thin film diode (TFD) or another type of display device that produces light.

Pixel portion 420 may include silicon layer(s). When activated, pixel portion 420 may become opaque and form images within an LCD display, for example. Pixel portion 420 may be referred to as the “light emitting” portion of TFT 410 although it should be understood that when pixel portion 420 is used in an LCD display, the “emitted light” is not produced by pixel portion 420. For example, the light emitted by pixel portion 420 may be produced by backlighting LEDs and/or light guides, etc. In other embodiments, (light generating non-LCD displays) pixel portion 420 may produce the emitted light when activated. For example, pixel portion 420 may produce light when current is applied via TFT driving logic 350.

Driving portion 430 may include base, emitter and collector regions or gate, drain and source regions of TFT 410 that connect driving current into pixel portion 420 of TFT 410. Driving portion 430 is not transparent and may be referred to as the “non-light emitting” portion of TFT 410.

Organic light emitting diode (OLED) 440 may include a light emitting diode that includes an electroluminescent layer made from organic compounds. Light generated from an OLED 440 may be used to produce light to form pixels within display 140. OLEDs 440 may also produce pixel displays within display 140 without requiring backlighting. OLEDs 440 may be produced/placed on driving portion 430 (or onto glass 450 as shown in FIG. 4D) using an ink-jet type of printing machine. For example, the organic compounds used to form OLEDs 440 may be sprayed onto an appropriate location (i.e., on driving portion 430 or onto glass 450).

Glass 450 may include a glass sheet or a similar transparent hard material. Glass 450 provides a mounting surface upon which TFTs 410 and OLEDs 440 may be located, as described below.

FIG. 4B shows a top view of an organic light emitting diode 440 located on top of a thin film transistor 410 that may be included within display 140. As would be seen by a user looking down on display 140, the visible components are OLED 440 and pixel portion 420 of TFT 410. In this manner, only the light emitting pixel portion 420 of the TFT and the OLED 440 may be used (seen) to create images within display 140.

FIG. 4C shows an exemplary display 140 that includes a number of TFTs 410 and a number of OLEDs 440 (as shown in FIGS. 4A and 4B). As shown, housing 101 may include a hard plastic material used to mount components within display 140. As shown in FIGS. 4A and 4B, as OLEDs 440 are located directly on top of driving portion 420 of TFTs 410, the visible (to the user) portions of display 140 may be pixel portions 420 and OLEDs 440. In this example, each pixel portion 420 and OLED 440 may represent one pixel within display 140. In other examples, there may be fewer OLEDs 440 than TFTs 410 included within display 140 to create a low density OLED display assembly. In further examples, there may areas within display 140 where one OLED 440 may be located on top of each TFT 410 to form a high density OLED display assembly within display 140, while other areas of display 140 may not contain any OLEDs 440. In still further examples, there may be areas within display 140 that include OLEDs 440 arranged in predetermined patterns. For example, displaying information that does not require a high density of pixels (such as a clock) or displaying information that does not change (or changes minimally) with time, such as an icon, OLEDs 440 may be arranged in specific patterns within an upper area within display 140. For example, OLEDs 440 may be arranged in an envelope pattern used to form (display) a message icon, and/or may be arranged in a series of ascending bars used to form (display) a signal strength icon, etc.

FIG. 4D shows another exemplary embodiment of display 140. In this example, an OLED 440 may be located on a top surface of glass 450, where OLED 440 may be located directly above the driving (non-light emitting) portion 430 of a TFT. In this example, the pixel portion 420 and driving portion 430 of a TFT are both located on the lower surface of glass 450. As shown by an up arrow, backlight (produced from illumination logic 330 and/or light guides, etc.) may be produced from a source below glass 450, where a user viewing display 140 may be looking/located above glass 450. In this manner, OLED 440 may still cover driving portion 430 of TFT, and may produce displays as described above in FIG. 4C.

FIG. 4E shows another exemplary embodiment of display 140. In this example, an OLED 440 and a TFT that includes a pixel portion 420 and driving portion 430 are both located on the lower surface of glass 450. In this example, OLED 440 may be located directly above the driving (non-light emitting) portion 430 of a TFT. As shown by an up arrow, backlight (produced from illumination logic 330 and/or light guides, etc.) may be produced from a source below glass 450. In this manner, OLED 440 may still cover driving portion 430 of TFT, and may produce displays as described above in FIG. 4C.

FIG. 4F shows another exemplary embodiment of display 140. In this example, an OLED 440 may be located directly on top of a TFT that includes a pixel portion 420 and driving portion 430, which includes an insulator portion 460 and a driving transistor 470 that drives OLED 440. In this example, the insulator portion 460, the driving transistor 470 and OLED 440 are located directly on top of the driving (non-light emitting) portion 430 of a TFT. In this manner, OLED 440 may still cover driving portion 430 of TFT, and may produce displays as described above.

As will be described in detail below, certain types of information, such as icons, that may be constantly displayed and require a small amount of display area, may be displayed via OLEDs 440. As OLEDs 440 require no backlighting and may be switched on/off in groups, the amount of power required from power supply 280 may be reduced. Other types of information that require higher quality resolution and backlighting, such as video information and character information, may be displayed via TFTs 410.

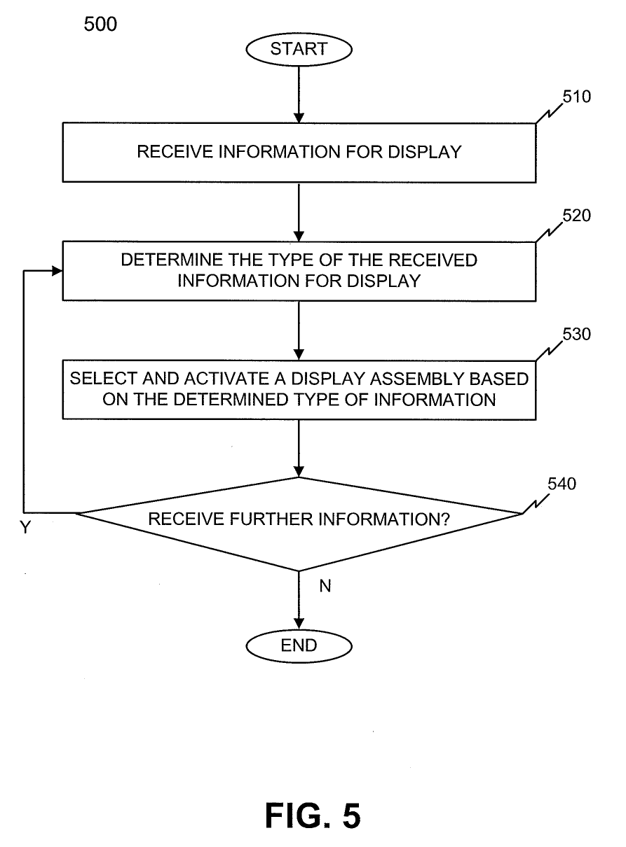

Operation of the display logic 240 and display assemblies shown in FIGS. 3 and 4A-4F are described below with reference to FIGS. 5-7.

FIG. 5 is a flowchart of exemplary processing consistent with the principles described herein. Process 500 may begin when information for display is received (block 510). For example, a text message (transmitted from another terminal) may be received by terminal 100. In response to receiving a text message, processing logic 210 may transmit information, for example, a message icon, to display logic 240 for displaying via display 140 (block 510). As described above, control logic 310 may receive this information from processing logic 210 and transmit this information to selection logic 320.

Selection logic 320 may receive the information for display and may determine the type of the received information (block 520). Continuing with this example, the received message icon may be determined by selection logic 320 as being a first type of information (block 520). As described above with reference to FIGS. 3 and 4A-4F, a first type of information may be displayed by a first display assembly (OLEDs 440) within display 140, while a second type of information may be displayed using a second display assembly (TFTs 410) within display 140. Selection logic 320 may select and activate a display assembly based on the determined type of received information (block 530). For example, as a message icon may be determined to be a first type of information, selection logic 320 may select OLED driving logic 360 (and OLEDs 440) to display the message icon via display 140 (block 530). Additionally, selection logic 320 may also determine that display 140 is not actively displaying any information, and select OLED driving logic 360 (and OLEDs 440) to display the message icon via display 140 (block 530).

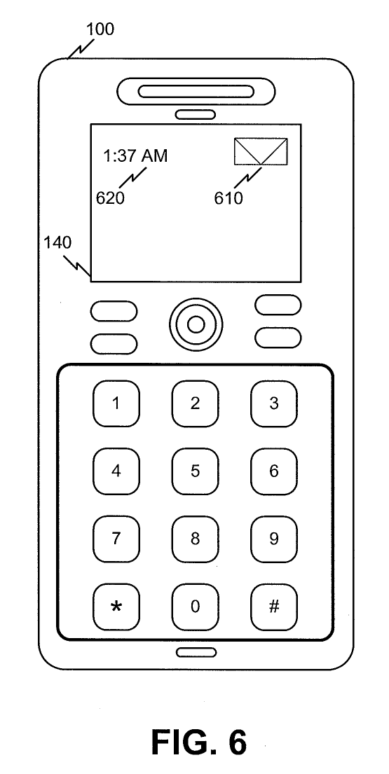

As shown in FIG. 6 for example, message icon 610 may be displayed via display 140 (block 530). After displaying the received information (block 530), it is determined if further information has been received for display (block 540). For example, after seeing that a message has been received by terminal 100, a user may operate one of control keys 120 to select a clock function to display the time of day. In this example, the activation/selection of a clock function is determined (YES in block 540) that further information has been received for display, and process 500 returns to block 520. The clock function may be determined by selection logic 320 as a first type of information for display (block 520). Selection logic 320 may then select and activate a display assembly based on the determined type of received information (block 530). For example, selection logic 320 may select OLED driving logic 360 (and OLEDs 440) to display the time of day via display 140 (block 530). As shown in FIG. 6, time of day 620 (1:37 AM) may be displayed via display 140 (block 530).

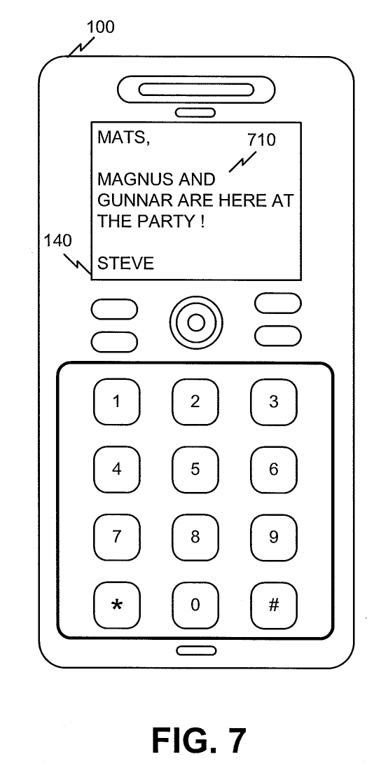

Continuing with this example, a user may depress a control key 120 in order to select (display) the received text message. The user selection to display the text message is determined (YES in block 540) that further information has been received for display, and process 500 returns to block 520. A text message may be determined by selection logic 320 as a second type of information for display (block 520). Selection logic 320 may then select and activate a display assembly based on the determined type of received information (block 530). For example, selection logic 320 may select TFT driving logic 350 (and TFTs 410) to display the received text message via display 140 (block 530). As shown in FIG. 7 for example, “Mats” (the user of terminal 100) may have received text message 710 “Mats, Magnus and Gunnar are here at the party! Steve.” Text message 710 may be displayed using TFTs 410 (block 530).

If Mats begins to reply to the received text message 710 (i.e., begins to enter characters via keys 112), entered characters may be received (YES in block 540) and determined as a second type of information (block 520) and displayed using TFTs 410 (as selected in block 530).

As described in the above scenario, selection logic 320 may control display 140 to display a first type of information using a low power OLED display assembly and may control display 140 to display a second type of information via TFT display assembly. Once the TFT display is active (e.g., after displaying text messages) selection logic 320 may control display 140 to display a first type of information using the TFT display assembly, as it is already activated.

In another example, a time of day (clock function), a message icon, a signal strength icon, and a battery power icon may all be constantly displayed via display 140. As described above, all these icons may be classified/determined as first types of information (block 520) and may all be displayed using OLED driving logic 360 and OLEDs 440 (block 530). Using OLEDs 440 to constantly display these icons reduces the amount of power required compared to the amount of power required to display these icons using TFTs 410, for example. As described above, each icon may be formed by a group of OLEDs 440 arranged in predetermined patterns (within an upper area of display 140), where each group of icons may be selected and activated with a single transistor switch, for example.

In other examples, the time of day (clock function), the message icon, the signal strength icon, and a battery power icon may be displayed via display 140 upon activation of a button or control key 120 on terminal 100. If a button (selecting an activating the display of an icon or another first type of information (block 520)) on terminal 100 is accidentally pressed, such as may happen when a user carries terminal 100 in their pocket, display 140 may remain in an “on” state for an extended period of time. Using the embodiments described above, displaying icons or information using OLEDs 440 (block 530) minimizes the power required from the battery (power supply 280). In this example, display 140 may remain “on” without draining the battery for extended periods of time, as the entire display 140 (and backlighting) is not required.

In further embodiments, if terminal 100 is used in bright ambient light conditions (such as detected by light sensor 340) OLEDs 440 and TFTs 410 may be used simultaneously to display information (block 530). For example, when terminal 100 is used outdoors, both display assemblies may be required to produce an image on display 140 with enough contrast to be visible to the user. For example, light sensor 340 may transmit an ambient light signal to selection logic 320, where selection logic 320 selects both TFT driving logic 350 and OLED driving logic 360 to display information. In this example, both the first and the second types of information may be displayed using both OLEDs 440 and TFTs 410.

In still further embodiments, if terminal 100 includes a light scanner (340), OLEDs 440 may be used to generate light for scanning. For example, when scanning a business card with terminal 100, light may be generated from OLEDs 440 to illuminate the business card. The light may then be reflected off the business card and received by light scanner 340. Terminal 100 may then compare and process the scanned information received via light sensor 340. In this manner, terminal 100 may use OLEDs 440 to generate light for scanning/identification functions.

### Conclusion

Implementations consistent with the principles of the embodiments may display information using one of a number of display assemblies based on the determined type of information for display and/or based on the determined on/off state of a display assembly.

The foregoing description of preferred embodiments of the embodiments provides illustration and description, but is not intended to be exhaustive or to limit the embodiments to the precise form disclosed. Modifications and variations are possible in light of the above teachings or may be acquired from practice of the embodiments.

While a series of acts has been described with regard to FIG. 5, the order of the acts may be modified in other implementations consistent with the principles of the embodiments. Further, non-dependent acts may be performed in parallel.

It will be apparent that aspects of the embodiments, as described above, may be implemented in many different forms of software, firmware, and hardware in the implementations illustrated in the figures. The actual software code or specialized control hardware used to implement these aspects is not limiting of the embodiments. Thus, the operation and behavior of the aspects were described without reference to the specific software code—it being understood that software and control hardware could be designed to implement the aspects based on the description herein.

Further, certain portions of the embodiments may be implemented as “logic” that performs one or more functions. This logic may include hardware, such as hardwired logic, an application specific integrated circuit, a field programmable gate array or a microprocessor, software, or a combination of hardware and software.

It should be emphasized that the term “comprises/comprising” when used in this specification and/or claims is taken to specify the presence of stated features, integers, steps or components but does not preclude the presence or addition of one or more other features, integers, steps, components or groups thereof.

Even though particular combinations of features are recited in the claims and/or disclosed in the specification, these combinations are not intended to limit the embodiments. In fact, many of these features may be combined in ways not specifically recited in the claims and/or disclosed in the specification.

No element, act, or instruction used in the present application should be construed as critical or essential to the embodiments unless explicitly described as such. Also, as used herein, the article “a” is intended to include one or more items. Where only one item is intended, the term “one” or similar language is used. Further, the phrase “based on” is intended to mean “based, at least in part, on” unless explicitly stated otherwise.

What is claimed is:

1. A mobile communication device, comprising:
a display assembly comprising:
a plurality of transistors, where each of the plurality of transistors includes a light-emitting region and a non-light-emitting region; and
a plurality of organic light emitting diodes (OLEDs), where the plurality of OLEDs are located directly on top of the non-light-emitting regions of the plurality of transistors;
a transistor driving circuit to provide current to the plurality of transistors;
an OLED driving circuit to provide current to the plurality of OLEDs; and
logic configured to:
receive and determine a type of information for display, and
select at least one of the transistor driving circuit or the OLED driving circuit based on the determined type of received information to display the received information.

2. The mobile communication device of claim 1, where the logic is further configured to:
select the OLED driving circuit when the received information for display is determined to be a first type of information; and
select the transistor driving circuit when the received information for display is determined to be a second type of information.

3. The mobile communication device of claim 2, where the first type of information includes at least one of a time of day, or an icon.

4. The mobile communication device of claim 3, further comprising:
a keypad for entering characters.

5. The mobile communication device of claim 4, where the second type of information includes at least one of text messages or characters entered via the keypad.

6. A method, comprising:
providing a display, where the display includes a first display assembly located on top of components of a second display assembly;
receiving information for display;
determining that the received information is one of a first type of information or a second type of information; and
selecting and activating one of the first display assembly or the second display assembly based on a determined information type to display the received information.

7. The method of claim 6, where the first display assembly includes a plurality of organic light emitting diodes (OLEDs).

8. The method of claim 7, where the second display assembly includes a plurality of transistors.

9. The method of claim 8, where the plurality of OLEDs are located on top of a non-light-emitting portion of the plurality of transistors.

10. The method of claim 6, where the selecting and activating one of the first or second display assemblies based on the determined information type to display the received information further includes:
selecting the first display assembly when the received information is determined to be the first type of information; and
selecting the second display assembly when the received information is determined to be the second type of information.

11. The method of claim 10, where the first type of information includes an icon.

12. The method of claim 11, where the second type of information includes information other than an icon.

13. The method of claim 11, where the first display assembly includes a pattern of a plurality of OLEDs arranged to form the icon.

14. The method of claim 13, where the icon includes at least one of a message icon, a signal strength icon or a battery power icon.

15. The method of claim 10, where the first type of information includes a time of day.

16. The method of claim 8, where the first display assembly does not require backlighting.

17. A device, comprising:
a display assembly comprising:
a plurality of transistors, where each of the plurality of transistors includes a light-emitting region and a non-light-emitting region; and
a plurality of organic light emitting diodes (OLEDs), where the plurality of OLEDs are located directly on top of the non-light-emitting regions of the plurality of transistors; and
logic configured to:
select and activate at least one of the plurality of transistors or the plurality of OLEDs to display information.

18. The device of claim 17, where the logic is further configured to:
select and activate the plurality of OLEDs when the information is an icon or time of day information; and
select and activate the plurality of transistors when the information is video information or character information.

19. The device of claim 18, where the plurality of OLEDs are arranged in a plurality of groups, where each group forms a pattern that is associated with an icon.

20. The device of claim 19, where the logic is further configured to:
select and activate the plurality of OLEDs and the plurality of transistors when bright ambient light conditions are determined.
